(19) United States
(12) Patent Application Publication
(10) Pub. No.: US 2012/0119631 A1
(43) Pub. Date: May 17, 2012

(54) COMPUTER CASE

(75) Inventor: Tung-Ke Lu, New Taipei City (TW)

(73) Assignee: GIGA-BYTE TECHNOLOGY CO.,LTD., New Taipei City (TW)

(21) Appl. No.: 13/111,971

(22) Filed: May 20, 2011

(30) Foreign Application Priority Data
Nov. 17, 2010 (TW) 99139554

(51) Int. Cl. H05K 5/02

(52) U.S. Cl. 312/223.2

(57) ABSTRACT

A computer case including a main case and a fixing unit is provided. The main case has a first wedging portion and a limiting portion. The fixing unit has a compressing portion, at least one lug and a second wedging portion. The compressing portion compresses a fixing side of a card to fix the card. The second wedging portion is at a first side of the compressing portion. The lug stretches from the compressing portion and is at a second side of the compressing portion. After the lug is connected the limiting portion, the first wedging portion wedges the second wedging portion to fix the fixing side of the card on the main case.

### CROSS-REFERENCE TO RELATED APPLICATION

This application claims the priority benefit of Taiwan application serial no. 99139554, filed Nov. 17, 2010. The entirety of the above-mentioned patent application is hereby incorporated by reference herein and made a part of this specification.

### BACKGROUND OF THE INVENTION

1. Field of the Invention

The invention is generally related to a computer case and more particularly to a computer case designed to facilitate assembly of cards.

2. Description of Related Art

In the present age of information and multimedia, computers have become one of the indispensable tools in our daily life. The type and quantity of interface cards which must be used in computers is increasing with the diversely development of computer applications. In prior art, screws are most commonly used to fasten the interface cards to computer case. However, this increases not only the number of screws used and also the steps of fastening. And steps of screw fastening using screw drivers are needed and it is rather time consuming. In addition, replacing the interface cards is quite often required in computers. The interface cards disassembling process may lead to problems of screw falling and cause short circuit or the surrounding components damaged. Moreover, the screws are often lost when they fall off into a computer case and it increases more problems for computer users.

### SUMMARY OF THE INVENTION

The present invention is directed to a computer case capable of fixing a card without screws.

The present invention is directed to a computer case for fixing a card. The computer case includes a main case and a fixing unit. The main case includes a first wedging portion and a limiting portion. The fixing unit includes a compressing portion, a second wedging portion and at least one lug. The compressing portion compresses a fixing side of the card to fix the card. The second wedging portion is at a first side of the compressing portion. The lug is stretching from the compressing portion and located at a second side of the compressing portion. After the lug of the fixing unit and the limiting portion of the main case are connected, the first wedging portion of the main case and the second wedging portion of the fixing unit are wedged to fix the fixing side of the card on the main case.

According to an embodiment of the invention, the computer case further includes a card frame at the main case, wherein a plurality of openings are disposed on the card frame and the openings are capable for accommodating the fixing side of the card. In addition, the limiting portion is located at the main case. The first wedging portion is disposed at the card frame. Furthermore, the computer case can further include a fixing frame fixing to the main case and the fixing frame is placed above the openings of the card frame. The limiting portion and the first wedging portion are at the fixing frame.

According to an embodiment of the invention, the first wedging portion defines is an opening. The second wedging portion is a protrusion which is capable to be embedded into the opening.

According to an embodiment of the invention, the compressing portion has a plurality of baffles compressing the fixing side of the card.

According to an embodiment of the invention, the compressing portion includes a plurality of elastic slices to increase the elastic stress and align the heights of the compressing portion for the baffles to compress the fixing side of the card more closely.

According to an embodiment of the invention, the fixing unit is an elastic element.

According to an embodiment of the invention, the material of the main case is metal.

According to an embodiment of the invention, the limiting portion is an arch bridge for the lug to pass through.

In light of the foregoing, the computer case of the present invention is capable for fixing the card by locking the fixing unit to the main case. It is rather convenient to use and the overall shortcomings caused by screw fixing can also be avoided.

In order to make the aforementioned and other features and advantages of the invention more comprehensible, embodiments accompanying figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a three dimensional perspective view of a computer case according to an embodiment of the invention.

FIG. 2A is an exploded diagram of a part of components of the computer case in FIG. 1.

FIG. 2B is a schematic diagram of the fixing unit in FIG. 2A.

FIG. 3 is a schematic diagram of a part of computer case of FIG. 1 in assembling process.

FIG. 4 is an exploded diagram of a part of components of computer case according to another embodiment of the invention.

### DESCRIPTION OF THE EMBODIMENTS

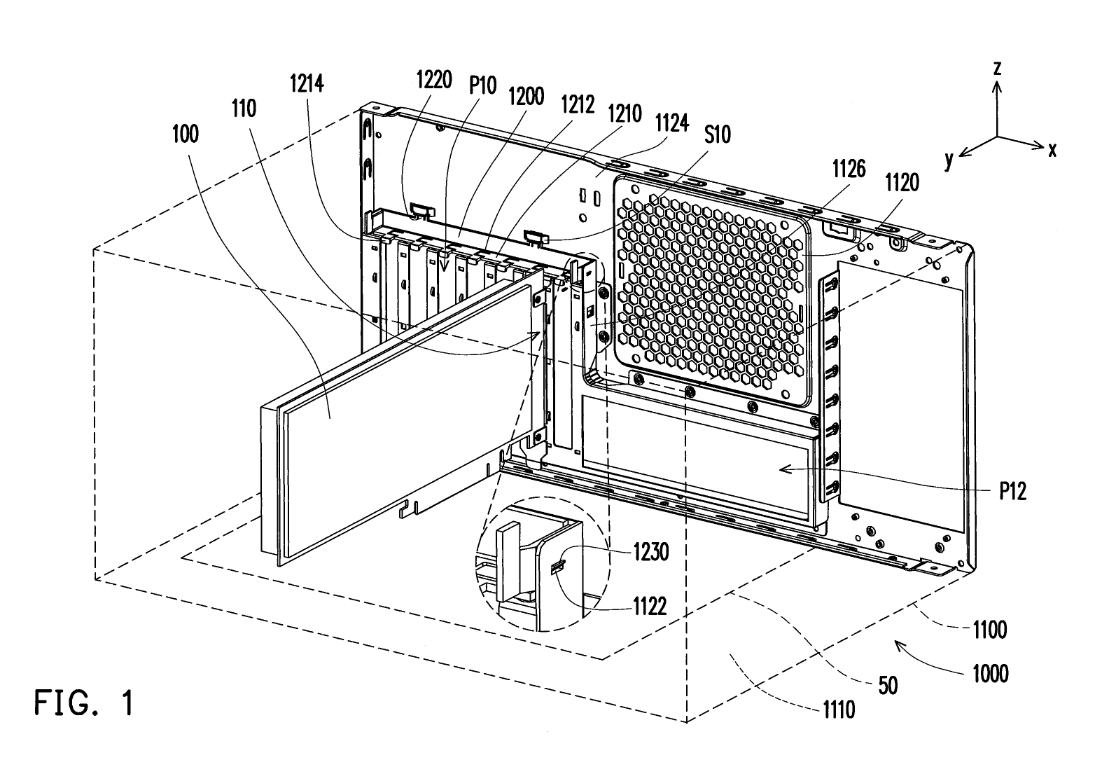

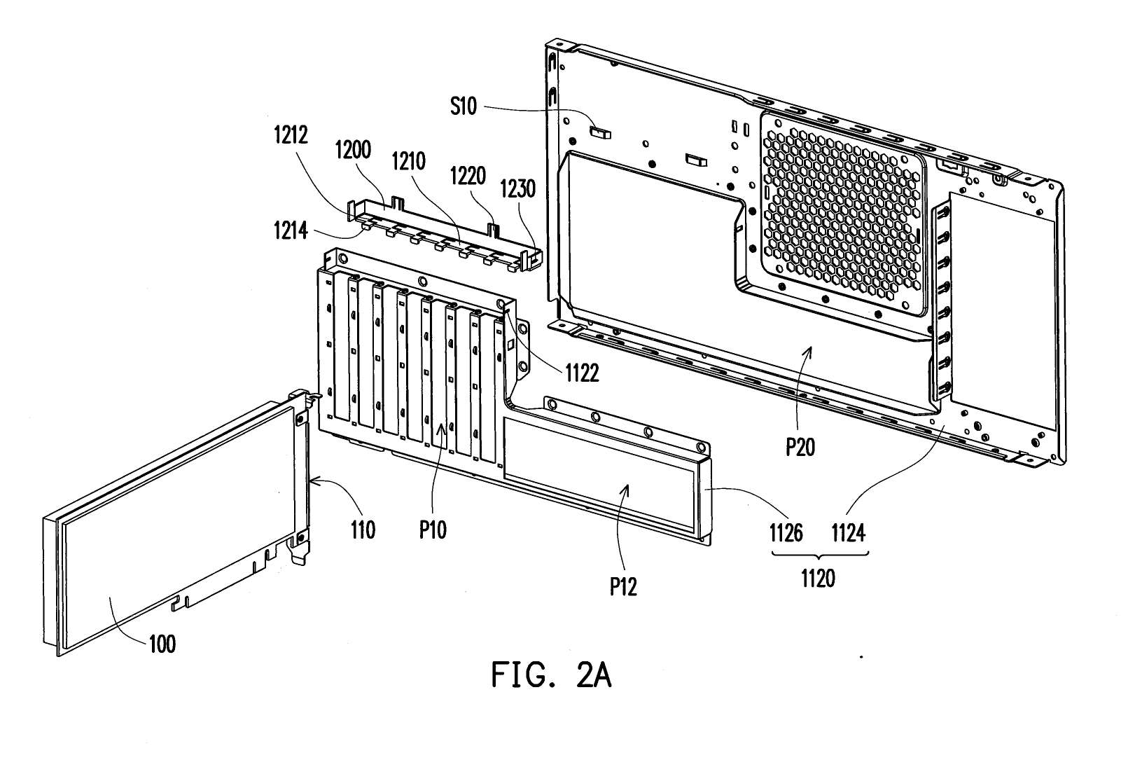

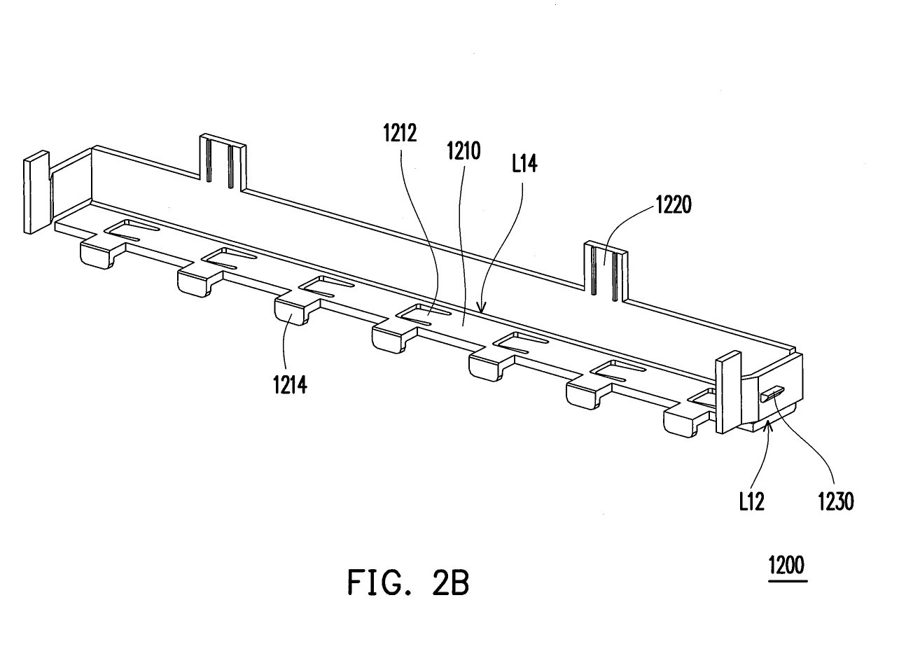

FIG. 1 is a three dimensional perspective view of a computer case according to an embodiment of the invention. FIG. 2A is an exploded diagram of a part of components of the computer case in FIG. 1. FIG. 2B is a schematic diagram of the fixing unit in FIG. 2A. Referring to FIG. 1 and FIG. 2A, the computer case 1000 of the present embodiment includes a main case 1100 and a fixing unit 1200. The main case 1100 has a side wall 1110 and a back wall 1120. For instance, the main case 1100, generally, is a cube and composed of the side wall 1110, the back wall 1120 and the other four walls (illustrated in dotted lines in FIG. 1). The side wall 1110 is used to carry a mother board 50 (illustrated in dotted lines in FIG. 1).

The back wall 1120 has a plurality of openings P10, at least one first wedging portion 1122 and at least one limiting portion S10 (two limiting portions are illustrated in FIG. 1 and FIG. 2A). A fixing side 110 of a card 100 which is plugged in the mother board 50 is placed at one of the openings P10. Though the number of cards 100 plugged in the mother board 50 is herein illustrated as one, for example, it can be up to the same with the number of openings P10. The cards 100 can be graphics cards, sound cards, network adapters or any other interface cards.

Referring to FIG. 1 and FIG. 2B, the fixing unit 1200 has a compressing portion 1210, at least one lug 1220 (two lugs are illustrated in FIG. 1 and FIG. 2B) and a second wedging portion 1230. The lug 1220 stretches from the second side L14 of the compressing portion 1210 and in the direction of away from the compressing portion 1210. According to FIG. 1, the compressing portion 1210 is approximately in parallel with the XY plane. The lug 1220 is approximately in parallel with the XY plane and stretches up from the compressing portion 1210. The second wedging portion 1230 is at the first side L12 of the compressing portion 1210, but the number of the second wedging portion 1230 is not limited as one thereto. It can be two compressing portions 1210 at the opposite sides of second wedging portion 1230 respectively.

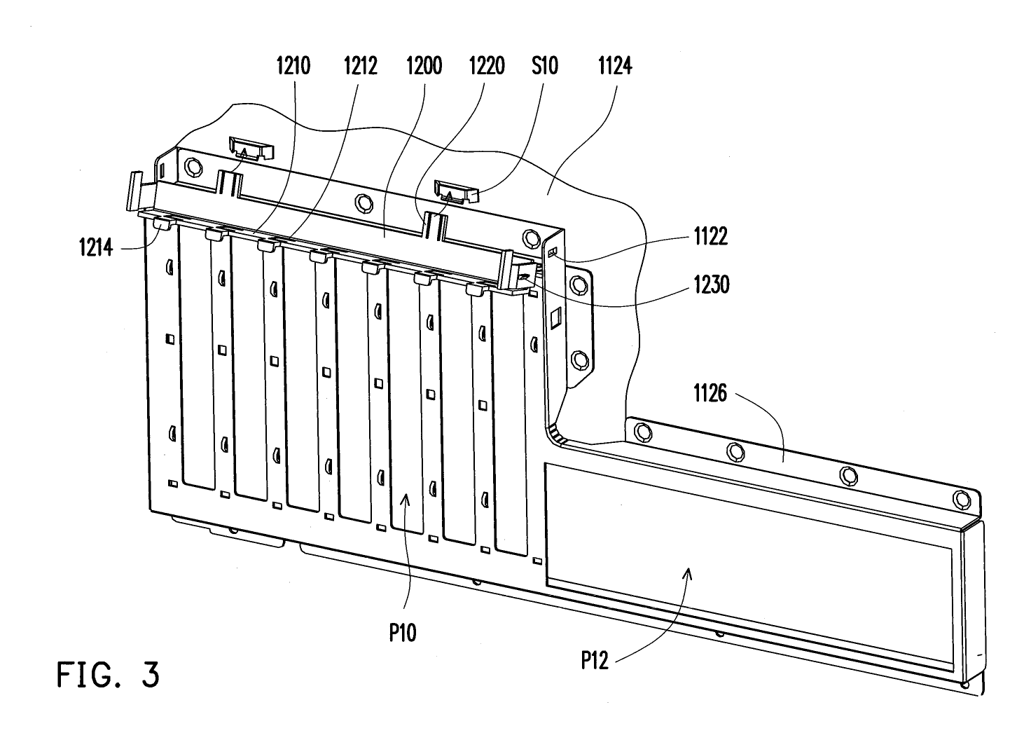

FIG. 3 is a schematic diagram of a part of computer case of FIG. 1 in assembling process. Referring to FIG. 1 and FIG. 3, after the card 100 is plugged to the mother board 50, the lug 1220 can be inserted into the limiting portion S10 from a side of the limiting portion S10 nearby the opening P10. For example, the lug 1220 can be inserted into the limiting portion S10 with the lug 1220 inclined at an angle to avoid the condition of difficult to be accomplished caused by the interference between the first wedging portion 1122 and the second wedging portion 1230 as soon as inserting it. After the front end of the lug 1220 is inserted into the limiting portion S10, the fixing unit 1200 can be rotated such that the lug 1220 is approximately in parallel with the back wall 1120. The first wedging portion 1122 and the second wedging portion 1230 will be wedged together at this moment, and the compressing portion 1210 compresses the fixing side 110 of the card 100. In this way, the card 100 can be firmly fixed at the mother board 50 by using the fixing unit 1200.

According to above descriptions, the computer case 1000 in this embodiment is capable for the card 100 to be simply and rapidly fixed by using the fixing unit 1200 whether the number of card 100 is one or in a plurality. It is no longer required operating with the screw drivers for fixing the cards 100 in this design, so the labour hours for assembling and the component costs are significantly reduced. Thus, the convenience is increased for the computer users in assembling process while replacing the cards 100. It is also no need to worry about the falling off screws in the computer case may damage the other expensive components.

Referring to FIG. 1 and FIG. 2A, the back wall 1120 of this embodiment includes a main plate 1124 and a card frame 1126. But the back wall 1120 can be a single element in another embodiment. The main plate 1124 has a mounting opening P20. The card frame 1126 is fixed with the main plate 1124 and covers the mounting opening P20. The opening P10 is at the card frame 1126. When the back wall 1120 is divided into the main plate 1124 and the card frame 1126, as long as the changes of the opening P10 position, caused by the place of the mother board 50 in which the card 100 is inserted is changed, are required, it is possible just to change the design of the card frame 1126. In this way, the design and manufacturing costs can be reduced by decreasing the chance of changing the back wall 1120 design. Additionally, if the card frame 1126 further includes, for example, an input-output opening P12, then an input-output panel (not shown) can be disposed. The specification of the input-output panel can be changed according to that of mother board 50.

Moreover, in an embodiment, the limiting portion S10 is at the main plate 1124 and the first wedging portion 1122 is at the card frame 1126. The limiting portion S10 is designed as an arch bridge and the space below the arch bridge is for inserting the lug 1220. The limiting portion S10 can be used to limit the lug 1220 be able to merely move along the Z direction. A guiding inclined plane S12 (illustrated in FIG. 3) can be set on a side of the limiting portion S10 nearby the opening P10 such that the lug 1220 can successfully insert.

Furthermore, the compressing portion 1210 has, for example, a plurality of elastic slices 1212 and a plurality of baffles 1214. The places of the elastic slices 1212 correspond to the openings P10 and can be formed at the opening of U-crack cleaving at the compressing portion 1210, but the appearances and the shapes are not limited in present invention. When there is no external force exerting thereon, the elastic slices 1212 are slightly protruding from the compressing portion 1210 toward the below direction in the FIG. 1. Thus, when the assembling of the fixing unit 1200 is completed, the elastic slices 1212 will deform from the fixing side 110 of the card 100 toward the upper direction in the FIG. 1. The deformation of the elastic slices 1212 will enhance the fixing effect regarded to the elastic stress exerted on the fixing side 110 of the card 100. This also can keep the heights in horizontal direction of the compressing portion 1210 the same. The baffles 1214 stretch from the edge of the compressing portion 1210 toward the below direction in the FIG. 1. When the assembling of the fixing unit 1200 is completed, the baffles 1214 clips the fixing side 110 of the card 100 to limit the movement of the card 100 along the Y direction.

In this embodiment, the first wedging portion 1122 is the opening of a plate which is in parallel with the XY plane, while the second wedging portion 1230 is the protrusion of a plate on the fixing unit 1200 which is in parallel with the XY plane. The first wedging portion 1122 can also be the protrusion while the second wedging portion 1230 can be the opening. Certainly, the first wedging portion 1122 and the second wedging portion 1230 can be replaced with any other appropriate wedging design and the details are not iterated herein.

In order to supply sufficient strength, in general, metal or other material with better strength is selected for the main case 1100, and plastic or other appropriate elastic material is selected for the fixing unit 1200. Plastic material can be used as the material of the fixing unit 1200 to avoid the card 100 being scratched and also reduce the costs and the overall weight.

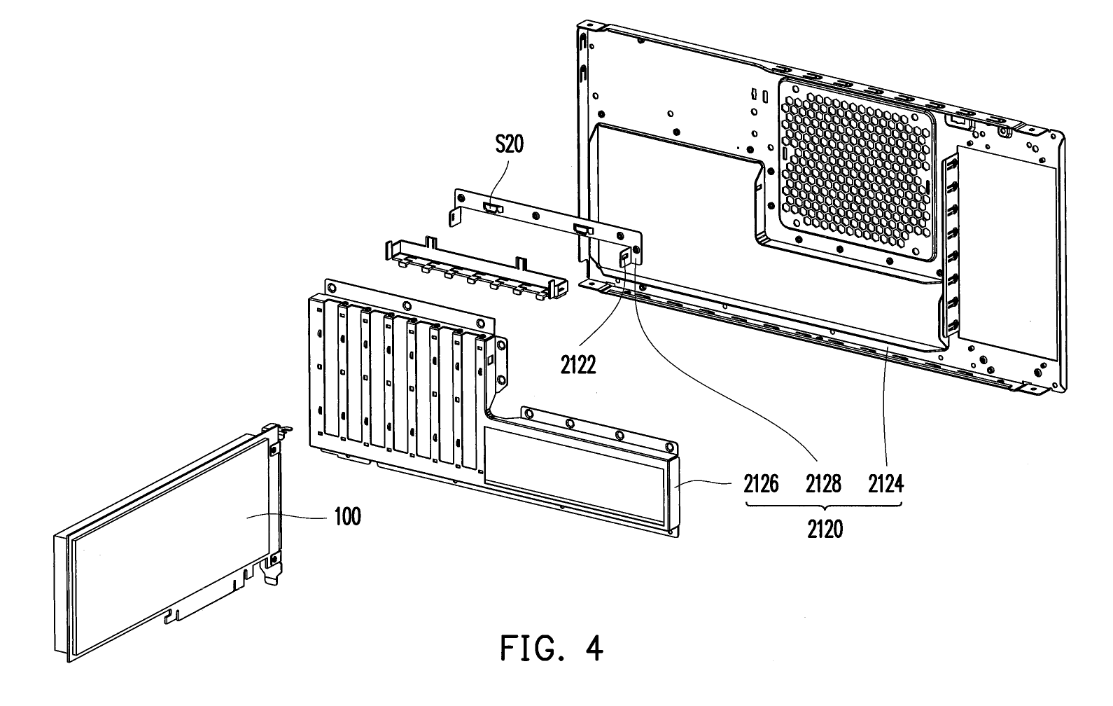

FIG. 4 is an exploded diagram of a part of components of computer case according to another embodiment of the invention. Referring to FIG. 4, the computer case of this embodiment is similar to the computer case 1000 illustrated in FIG. 1. Only the difference is illustrated herein. The back wall 2120 of this embodiment includes a main plate 2124, a card frame 2126 and a fixing frame 2128. The difference of the main plate 2124 between the main plate 1124 of FIG. 1 is the lack of the limiting portion S10. The difference between the card frame 2126 and the card frame 1126 of FIG. 1 is the lack of the first wedging portion 1122. The fixing frame 2128 can be fixed with the main plate 2124 and placed at the side of card frame 2126, and the fixing frame 2128 has the limiting portion S20 and the first wedging portion 2122. In other words, the difference between the computer case of this embodiment and the computer case 1000 of FIG. 1 is the design of disposing the limiting portion S20 and the first wedging portion 2122 on the fixing frame 2128 which is parted from the main plate 2124.

In summary, in the computer case of the present invention, the card is fixed by wedging the fixing unit to the main case. The computer case of the present invention is provided with the advantages of having the capability of simply and rapidly fixing the cards without using the screw drivers, reducing the labour hours of assembling process and component costs, increasing the convenience of replacing cards and reducing the overall risks of the surrounding components get damaged.

Although the invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A computer case for fixing a card, comprising:
a main case, having a first wedging portion and a limiting portion; and
a fixing unit; comprising:
a compressing portion, compressing a fixing side of the card to fix the card;
a second wedging portion at a first side of the compressing portion; and
at least one lug, stretching from the compressing portion and located at a second side of the compressing portion; and
wherein, after the lug of the fixing unit and the limiting portion of the main case are connected, the first wedging portion of the main case wedges the second wedging portion of the fixing unit to fix the fixing side of the card on the main case.

2. The computer case according to claim 1, further comprising a card frame disposed in the main case, wherein a plurality of openings are at the card frame, and the openings are capable for accommodating the fixing side of the card.

3. The computer case according to claim 2, wherein the limiting portion is located at the main case, the first wedging portion is disposed at the card frame.

4. The computer case according to claim 2, further comprising a fixing frame fixing to the main case and placed above the openings of the card frame, and the limiting portion and the first wedging portion are at the fixing frame.

5. The computer case according to claim 1, wherein the first wedging portion defines an opening, the second wedging portion is a protrusion which is capable to be embedded into the opening.

6. The computer case according to claim 1, wherein the compressing portion having a plurality of baffles compressing the fixing side of the card.

7. The computer case according to claim 6, wherein the compressing portion comprising a plurality of elastic slices to increase the elastic stress and align the heights of the compressing portion for the baffles to compress the fixing side of the card closely.

8. The computer case according to claim 1, wherein the fixing unit is an elastic element.

9. The computer case according to claim 1, wherein the material of the main case is metal.

10. The computer case according to claim 1, wherein the limiting portion is an arch bridge for the lug to pass through.
